(19) United States
(12) Patent Application Publication
(10) Pub. No.: US 2025/0268029 A1
(43) Pub. Date: Aug. 21, 2025

(54) DISPLAY DEVICE

(71) Applicant: LG Display Co., Ltd., Seoul (KR)

(72) Inventors: Hyesun SON, Paju-si (KR); Sejin JANG, Paju-si (KR); JunHa HWANG, Paju-si (KR); SoJung PARK, Paju-si (KR)

(21) Appl. No.: 18/934,936

(22) Filed: Nov. 1, 2024

(30) Foreign Application Priority Data
Feb. 21, 2024 (KR) 10-2024-0025229

(51) Int. Cl. H10K 59/126; H10K 59/38; H10K 59/80; H10K 102/00

(52) U.S. Cl. CPC H10K 59/126; H10K 59/38; H10K 59/873; H10K 2102/311; H10K 2102/351

(57) ABSTRACT

A flexible or foldable display device is disclosed that is capable of increasing the reliability of the folding area by including a first adhesive member positioned on the color filter layer, disposed in the folding area, and including an ultraviolet absorbing material of a first mole percent, and a second adhesive member disposed on the first adhesive member in the folding area and including an ultraviolet absorbing material of a second mole percent smaller than the first mole percent.

### CROSS-REFERENCE TO RELATED APPLICATION

This application claims priority from Korean Patent Application No. 10-2024-0025229, filed on Feb. 21, 2024, which is hereby incorporated by reference for all purposes as if fully set forth herein.

### BACKGROUND

### Technical Field

Embodiments of the disclosure relate to a display device.

### Description of Related Art

The importance of display devices is increasing with the development of multimedia. In response to this, various types of display devices, such as organic light emitting display devices, liquid crystal display devices, etc., are being used.

As display technology advances, research and development on display devices with flexible displays are actively underway.

Flexible displays may extend or shorten the display screen by folding, bending, or sliding, contributing greatly to reducing the size of the display device or changing the design.

### BRIEF SUMMARY

A stacked structure that uses a color filter layer instead of a polarizer has been developed for organic light emitting display devices, but when applied to flexible displays, suffers from poor folding reliability. Accordingly, the inventors of the disclosure have invented a display device that may enhance the reliability of the folding area through UV exposure.

Embodiments of the disclosure may provide a display device capable of increasing the reliability of the folding area.

Embodiments of the disclosure may provide a display device capable of increasing the reliability of a flexible display to which a color filter layer is applied.

Embodiments of the disclosure may provide a display device, comprising a substrate including a first non-folding area, a second non-folding area, and a folding area positioned between the first non-folding area and the second non-folding area, a plurality of light emitting elements disposed on the substrate, an encapsulation layer disposed on the plurality of light emitting elements, a color filter layer disposed on the encapsulation layer, a first adhesive member positioned on the color filter layer, disposed in the folding area, and including an ultraviolet absorbing material of a first mole percent, and a second adhesive member disposed on the first adhesive member in the folding area and including the ultraviolet absorbing material of a second mole percent smaller than the first mole percent.

Embodiments of the disclosure may provide a display device comprising a substrate including a first non-folding area, a second non-folding area, and a folding area positioned between the first non-folding area and the second non-folding area, a plurality of light emitting elements disposed on the substrate, an encapsulation layer disposed on the plurality of light emitting elements, a color filter layer disposed on the encapsulation layer, a first adhesive member positioned on the color filter layer, including a concave portion including a flat portion and an inclined portion surrounding the flat portion and overlapping the folding area, and including an ultraviolet absorbing material of a first mole percent, and a second adhesive member positioned in the concave portion of the first adhesive member, and including the ultraviolet absorbing material of a second mole percent smaller than the first mole percent.

Embodiments of the disclosure may provide a display device comprising a substrate including a first non-folding area, a second non-folding area, and a folding area positioned between the first non-folding area and the second non-folding area, a plurality of light emitting elements disposed on the substrate, an encapsulation layer disposed on the plurality of light emitting elements, a color filter layer disposed on the encapsulation layer, and an adhesive member disposed on the color filter layer, disposed in the folding area, and including a first portion adjacent to the color filter layer and a second portion on the first portion, wherein an ultraviolet absorption rate of the first portion is larger than an ultraviolet absorption rate of the second portion.

According to embodiments of the disclosure, there may be provided a display device capable of increasing the reliability of the folding area.

According to embodiments of the disclosure, there may be provided a display device capable of low-power driving by increasing the reliability of a color filter layer-applied flexible display.

### BRIEF DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIGS. 1A and 1B are perspective views illustrating a display device according to embodiments of the disclosure;

FIG. 2 is a view illustrating a configuration of a system of a display device according to embodiments of the disclosure;

FIG. 3 is an equivalent circuit diagram illustrating a subpixel in a display panel according to embodiments of the disclosure;

FIG. 4 is a cross-sectional view illustrating a display panel according to embodiments of the disclosure;

FIGS. 5A, 5B, 5C, and 5D are views illustrating an example of a cross-sectional structure taken along A-A′ of FIG. 1A;

FIG. 6 is a graph illustrating changes in value depending on the presence or absence of a UV absorbing material of an adhesive member in a display device according to embodiments of the disclosure; and

FIGS. 7A, 7B, and 7C are views schematically illustrating a process of forming a structure of a display device according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to”, “contacts or overlaps”, etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

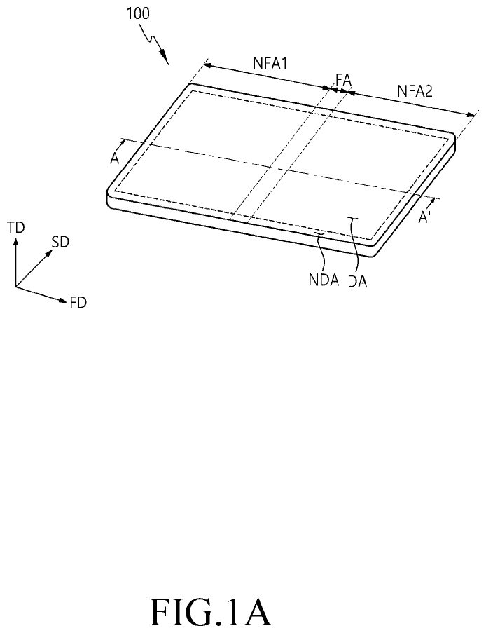

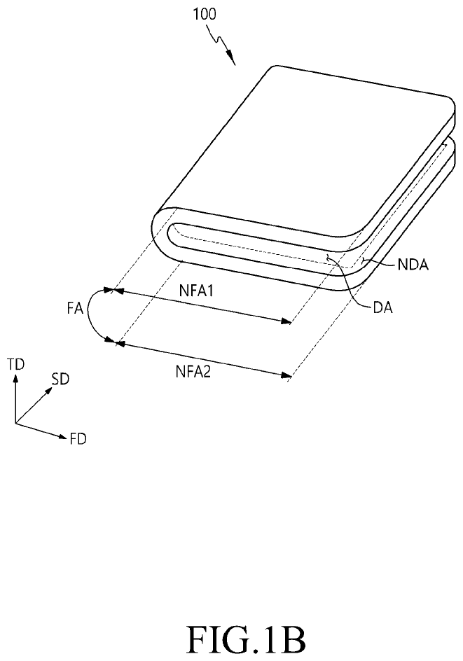

FIGS. 1A and 1B are perspective views illustrating a display device according to embodiments of the disclosure.

Hereinafter, the first direction FD, the second direction SD, and the third direction TD cross each other in different directions.

For example, the first direction FD may be a length direction, the second direction SD may be a width direction, and the third direction TD may be a thickness direction.

Referring to FIGS. 1A and 1B, a display device 100 according to embodiments of the disclosure may include various devices for displaying a screen or an image.

The display device 100 may include, but is not limited to, e.g., a smartphone, a mobile phone, a tablet personal computer (PC), a personal digital assistant (PDA), a portable multimedia player (PMP), a television, a game console, a wristwatch-type electronic device, a head mounted display, a monitor of a personal computer, a notebook computer, a car navigation system, a car dashboard, a digital camera, a camcorder, an external sign board, an electronic display, various medical devices, various inspection devices, various home appliances including a display such as a refrigerator or a washing machine, an Internet of things device, or the like.

Referring to FIG. 1A, the display device 100 may have a rectangular shape on a plane.

In an embodiment, the display device 100 may have two opposite long sides extending in the first direction FD and two opposite short sides extending in the second direction SD crossing the first direction FD on a plane.

However, the disclosure is not limited thereto, and the display device 100 may have various shapes.

The display device 100 may include a display area DA and a non-display area NDA.

The display area DA may display an image or video.

A plurality of pixels may be disposed in the display area DA.

As illustrated in FIG. 1A, the display area DA may be disposed on an upper surface of the display device 100, but is not limited thereto, and the display area DA may be also disposed on at least one of a lower surface and a side surface of the display device 100.

The non-display area NDA may not display an image or video.

The non-display area NDA may be disposed around the display area DA.

The non-display area NDA may surround the display area DA.

The non-display area NDA may be, e.g., an area in which a light blocking member such as a black matrix is disposed.

In an embodiment, the display area DA may have a rectangular shape, and the non-display area NDA may be disposed around four sides of the display area DA, but is not limited thereto.

Referring to FIGS. 1A and 1B, the display device 100 may be a foldable display device capable of being folded or unfolded.

The display device 100 may be divided into a folding area FA and non-folding areas NFA1 and NFA2.

The folding area FA may be an area that is folded or bent when the display device 100 is folded.

The non-folding areas NFA1 and NFA2 may be areas that maintain flatness without folding or bending when the display device 100 is folded.

The non-folding areas NFA1 and NFA2 may include a first non-folding area NFA1 and a second non-folding area NFA2.

The first non-folding area NFA1 and the second non-folding area NFA2 may be arranged in the first direction FD, and the folding area FA may be disposed between the first non-folding area NFA1 and the second non-folding area NFA2.

The display device 100 may be folded so that the first non-folding area NFA1 overlaps the second non-folding area NFA2, or may be bent so that the first non-folding area NFA1 is inclined with respect to the second non-folding area NFA2 or unfolded flat.

For example, the display device 100 may be folded so that the first non-folding area NFA1 forms an angle of 0 degrees or more and less than 180 degrees with respect to the second non-folding area NFA2, or may be unfolded so that the first non-folding area NFA1 forms an angle of 180 degrees with respect to the second non-folding area NFA2.

Referring to FIG. 1A, when the display device 100 is unfolded, the first non-folding area NFA1, the folding area FA, and the second non-folding area NFA2 may be flatly unfolded so as not to overlap each other in the third direction TD.

Referring to FIG. 1B, when the display device 100 is folded, the first non-folding area NFA1 and the second non-folding area NFA2 may overlap each other in the third direction TD.

Further, although not illustrated, when the display device 100 is folded, the first non-folding area NFA1 and the second non-folding area NFA2 may be disposed to be inclined with each other.

In this case, at least a portion of the first non-folding area NFA1 and at least a portion of the second non-folding area NFA2 may or may not overlap each other in the third direction TD.

In an embodiment, one folding area FA and two non-folding areas NFA1 and NFA2 are illustrated, but the number and arrangement of the folding area FA and the non-folding area NFA are not limited thereto.

Referring to FIG. 1B, the display device 100 may be in-folded.

In-folding may be folding so that at least a portion of the display area DA is not exposed to the outside during folding.

For example, when a portion of the display area DA is folded to face another portion of the display area DA and the display device 100 is completely folded, the display area DA may be surrounded by at least one other member forming the exterior of the display device 100 not to be exposed to the outside.

The display device 100 may have an unfolding state in which the display device 100 is unfolded and a folding state in which the display device 100 is folded.

The display device 100 may be configured to be freely switchable to the unfolding state and the folding state.

Referring to FIG. 1A, the unfolding state may be a state in which the first non-folding area NFA1 and the second non-folding area NFA2 are disposed side by side on one plane.

Referring to FIG. 1B, the folding state may be a state in which the first non-folding area NFA1 and the second non-folding area NFA2 are disposed parallel to each other and completely overlap each other in the third direction TD.

Although not shown, the folding state may further include a state in which the first non-folding area NFA1 and the second non-folding area NFA2 are half-folded.

In other words, the first non-folding area NFA1 may be disposed to be inclined with respect to the second non-folding area NFA2.

In this case, the first non-folding area NFA1 and the second non-folding area NFA2 may partially overlap or may not overlap depending on the angle between the first non-folding area NFA1 and the second non-folding area NFA2.

For example, the unfolding state may be a state in which the angle between the first non-folding area NFA1 and the second non-folding area NFA2 of the display device 100 is 180 degrees, and the folding state may be a state in which the angle between the first non-folding area NFA1 and the second non-folding area NFA2 of the display device 100 is 0 degrees or more and less than 180 degrees or 180 degrees or more and less than 360 degrees.

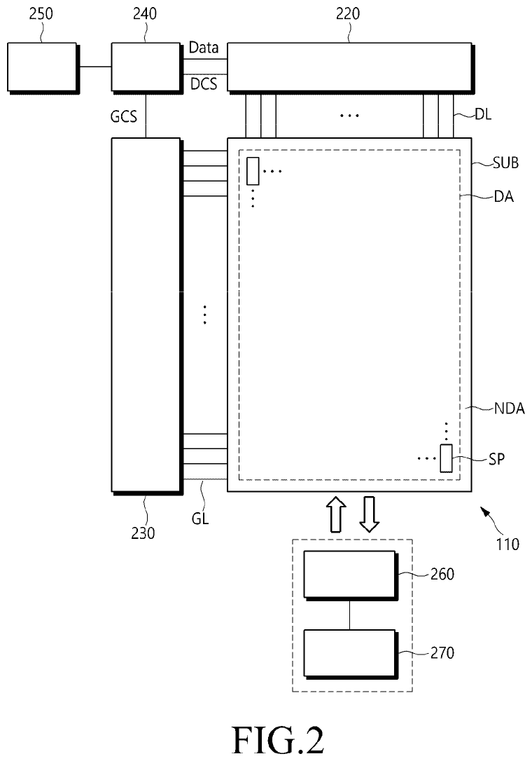

FIG. 2 is a view illustrating a system configuration of a display device 100 according to embodiments of the disclosure.

Referring to FIG. 2, a display device 100 may include a display panel 110 and display driving circuits, as components for displaying images.

The display driving circuits are circuits for driving the display panel 110 and may include a data driving circuit 220, a gate driving circuit 230, and a display controller 240.

The display panel 110 may include a display area DA in which images are displayed and a non-display area NDA in which no image is displayed.

The non-display area NDA may be an outer area of the display area DA and be referred to as a bezel area.

The whole or part of the non-display area NDA may be an area visible from the front surface of the display device 100 or an area that is bent and not visible from the front surface of the display device 100.

The display panel 110 may include a substrate SUB and a plurality of subpixels SP disposed on the substrate SUB.

The display panel 110 may further include various types of signal lines to drive the plurality of subpixels SP.

The display device 100 according to embodiments of the disclosure may be a liquid crystal display device or a self-emission display device in which the display panel 110 emits light by itself.

When the display device 100 according to the embodiments of the disclosure is a self-emission display device, each of the plurality of subpixels SP may include a light emitting element.

For example, the display device 100 according to embodiments of the disclosure may be an organic light emitting diode display device in which the light emitting element is implemented as an organic light emitting diode (OLED).

As another example, the display device 100 according to embodiments of the disclosure may be an inorganic light emitting display device in which the light emitting element is implemented as an inorganic material-based light emitting diode.

As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100.

For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other.

Each of the plurality of data lines DL may be disposed while extending in a first direction.

Each of the plurality of gate lines GL may be disposed while extending in a second direction.

Here, the first direction may be a column direction and the second direction may be a row direction.

The first direction may be also the row direction, and the second direction may be also the column direction.

The data driving circuit 220 is a circuit for driving the plurality of data lines DL, and may output data signals to the plurality of data lines DL.

The gate driving circuit 230 is a circuit for driving the plurality of gate lines GL, and may output gate signals to the plurality of gate lines GL.

The display controller 240 is a device for controlling the data driving circuit 220 and the gate driving circuit 230 and may control driving timings for the plurality of data lines DL and driving timings for the plurality of gate lines GL.

The display controller 240 may supply a data driving control signal DCS to the data driving circuit 220 to control the data driving circuit 220 and may supply a gate driving control signal GCS to the gate driving circuit 230 to control the gate driving circuit 230.

The display controller 240 may receive input image data from the host system 250 and supply image data Data to the data driving circuit 220 based on the input image data.

The data driving circuit 220 may supply data signals to the plurality of data lines DL according to the driving timing control of the display controller 240.

The data driving circuit 220 may receive digital image data Data from the display controller 240 and may convert the received image data Data into analog data signals and output the analog data signals to the plurality of data lines DL.

The gate driving circuit 230 may supply gate signals to the plurality of gate lines GL according to the timing control of the display controller 240.

The gate driving circuit 230 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

For example, the data driving circuit 220 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 230 may be connected with the display panel 110 by TAB method or connected to a bonding pad of the display panel 110 by a COG or COP method or may be connected with the display panel 110 according to a COF method.

Alternatively, the gate driving circuit 230 may be formed in a gate in panel (GIP) type, in the non-display area NDA of the display panel 110.

The gate driving circuit 230 may be disposed on the substrate or may be connected to the substrate.

In other words, the gate driving circuit 230 that is of a GIP type may be disposed in the non-display area NDA of the substrate.

The gate driving circuit 230 that is of a chip-on-glass (COG) type or chip-on-film (COF) type may be connected to the substrate.

Meanwhile, at least one of the data driving circuit 220 and the gate driving circuit 230 may be disposed in the display area DA of the display panel 110.

For example, at least one of the data driving circuit 220 and the gate driving circuit 230 may be disposed not to overlap the subpixels SP or to overlap all or some of the subpixels SP.

The data driving circuit 220 may be connected to one side (e.g., an upper or lower side) of the display panel 110.

Depending on the driving scheme or the panel design scheme, data driving circuits 220 may be connected with both the sides (e.g., both the upper and lower sides) of the display panel 110, or two or more of the four sides of the display panel 110.

The gate driving circuit 230 may be connected to one side (e.g., a left or right side) of the display panel 110.

Depending on the driving scheme or the panel design scheme, gate driving circuits 230 may be connected with both the sides (e.g., both the left and right sides) of the display panel 110, or two or more of the four sides of the display panel 110.

The display controller 240 may be implemented as a separate component from the data driving circuit 220, or the display controller 140 and the data driving circuit 220 may be integrated into an integrated circuit (IC).

The display controller 240 may be a timing controller used in typical display technology, a control device that may perform other control functions as well as the functions of the timing controller, or a control device other than the timing controller, or may be a circuit in the control device.

The display controller 240 may be implemented as various circuits or electronic components, such as an integrated circuit (IC), a field programmable gate array (FPGA), an application specific integrated circuit (ASIC), or a processor.

The display controller 240 may be mounted on a printed circuit board or a flexible printed circuit and may be electrically connected with the data driving circuit 220 and the gate driving circuit 230 through the printed circuit board or the flexible printed circuit.

The display controller 240 may transmit/receive signals to/from the data driving circuit 220 according to one or more predetermined interfaces.

The interface may include, e.g., a low voltage differential signaling (LVDS) interface, an EPI interface, and a serial peripheral interface (SP).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit 260 that drives and senses the touch sensor and generates and outputs touch sensing data and a touch controller 270 that may detect an occurrence of a touch or the position of the touch using touch sensing data.

The touch sensor may include a plurality of touch electrodes.

The touch sensor may further include a plurality of touch lines for electrically connecting the plurality of touch electrodes and the touch driving circuit 260.

The touch sensor may be present in a touch panel form outside the display panel 110 or may be present inside the display panel 110.

When the touch panel, in the form of a touch panel, exists outside the display panel 110, the touch panel is referred to as an external type.

When the touch sensor is of the external type, the touch panel and the display panel 110 may be separately manufactured or may be combined during an assembly process.

The external-type touch panel may include a touch panel substrate and a plurality of touch electrodes on the touch panel substrate.

When the touch sensor is present inside the display panel 110, the touch sensor may be formed on the substrate SUB, together with signal lines and electrodes related to display driving, during the manufacturing process of the display panel 110.

The touch driving circuit 260 may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen).

According to the self-capacitance sensing scheme, each of the plurality of touch electrodes may serve both as a driving touch electrode and as a sensing touch electrode.

The touch driving circuit 260 may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes.

According to the mutual-capacitance sensing scheme, the plurality of touch electrodes are divided into driving touch electrodes and sensing touch electrodes.

The touch driving circuit 260 may drive the driving touch electrodes and sense the sensing touch electrodes.

The touch driving circuit 260 and the touch controller 270 included in the touch sensing circuit may be implemented as separate devices or as a single device.

The touch driving circuit 260 and the data driving circuit 220 may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

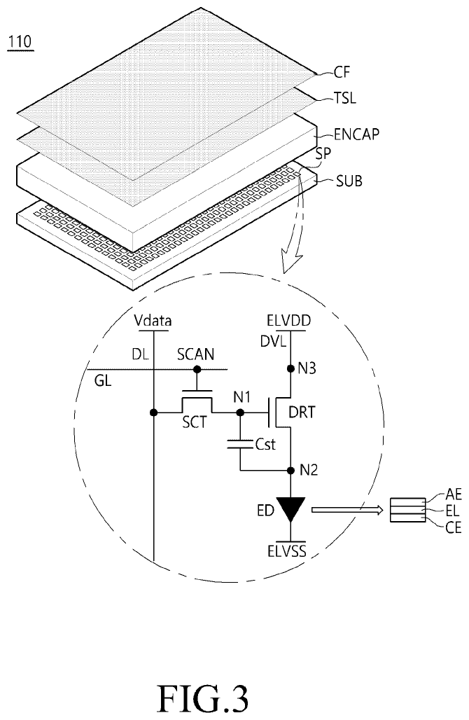

FIG. 3 is an equivalent circuit of a subpixel SP in a display panel 110 according to embodiments of the disclosure.

Each subpixel SP disposed in the display area DA of the display panel 110 may include an light emitting element ED, a driving transistor DRT for driving the light emitting element ED, a scan transistor SCT for transferring a data voltage Vdata to a first node N1 of the driving transistor DRT, and a storage capacitor Cst for maintaining a constant voltage during one frame.

The driving transistor DRT may include the first node N1 to which the data voltage may be applied, a second node N2 electrically connected with the light emitting element ED, and a third node N3 to which a driving voltage ELVDD is applied from a driving voltage line DVL.

The first node N1 in the driving transistor DRT may be a gate node, the second node N2 may be a source node or a drain node, and the third node N3 may be the drain node or the source node.

The light emitting element ED may include an anode electrode AE, a light emitting layer EL, and a cathode electrode CE.

The anode electrode AE may be a pixel electrode disposed in each subpixel SP and be electrically connected to the second node N2 of the driving transistor DRT of each subpixel SP.

The cathode electrode CE may be a common electrode commonly disposed in the plurality of subpixels SP, and a base voltage ELVSS may be applied thereto.

For example, the anode electrode AE may be a pixel electrode, and the cathode electrode CE may be a common electrode.

Conversely, the anode electrode AE may be a common electrode, and the cathode electrode CE may be a pixel electrode.

Hereinafter, for convenience of description, it is assumed that the anode electrode AE is a pixel electrode and the cathode electrode CE is a common electrode.

The light emitting element ED may be an organic light emitting diode (OLED), an inorganic light emitting diode, or a quantum dot light emitting element.

In this case, when the light emitting element ED is an organic light emitting diode, the light emitting layer EL of the light emitting element ED may include an organic light emitting layer including an organic material.

The scan transistor SCT may be on/off controlled by a scan signal SCAN, which is a gate signal, applied via the gate line GL and be electrically connected between the first node N1 of the driving transistor DRT and the data line DL.

The storage capacitor Cst may be electrically connected between the first node N1 and second node N2 of the driving transistor DRT.

Each subpixel SP may have a 2T (transistor) 1C (capacitor) structure which includes two transistors DRT and SCT and one capacitor Cst as shown in FIG. 3 and, in some cases, each subpixel SP may further include one or more transistors or one or more capacitors.

The storage capacitor Cst may be an external capacitor intentionally designed to be outside the driving transistor DRT, but not a parasite capacitor (e.g., Cgs or Cgd) which is an internal capacitor that may be present between the first node N1 and the second node N2 of the driving transistor DRT.

Each of the driving transistor DRT and the scan transistor SCT may be an n-type transistor or a p-type transistor.

Further, each of the driving transistor DRT and the scan transistor SCT may be composed of a low-temperature polycrystalline silicon transistor.

However, without limitations thereto, at least one may be composed of an oxide thin film transistor.

Since the circuit elements (particularly, the light emitting element ED) in each subpixel SP are vulnerable to external moisture or oxygen, an encapsulation layer ENCAP may be disposed to cover the light emitting elements ED to prevent penetration of external moisture or oxygen into the circuit elements (particularly, the light emitting element ED).

Further, referring to FIG. 3, a touch electrode layer TSL may be disposed on the encapsulation layer ENCAP.

A color filter layer CF may be disposed on the touch electrode layer TSL.

The color filter layer CF may include a plurality of color filters.

The touch electrode layer TSL and the plurality of color filters are described below.

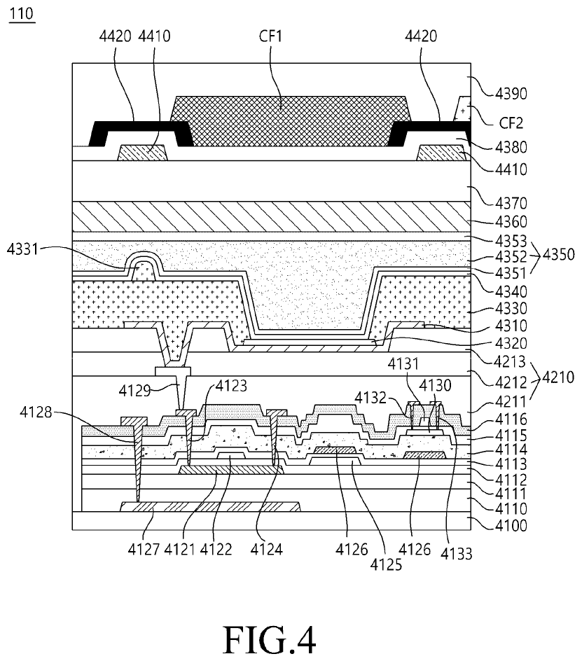

FIG. 4 is a cross-sectional view illustrating a display panel according to embodiments of the disclosure.

Referring to FIG. 4, a display panel 110 according to embodiments of the disclosure includes a substrate 4100, an insulation layer 4210 positioned on the substrate, an anode electrode 4310 positioned on the insulation layer 4210, a bank layer 4330 positioned on the anode electrode 4310 and the insulation layer 4210, a light emitting layer 4320 positioned on the anode electrode 4310, a cathode electrode 4340 positioned on the light emitting layer 4320 and the bank layer 4330, an encapsulation layer 4350 positioned on the cathode electrode 4340, a touch buffer layer 4360 positioned on the encapsulation layer 4350, a touch interlayer insulation layer 4370 positioned on the touch buffer layer 4360, and a passivation layer 4380 positioned on the touch interlayer insulation layer 4370.

The display panel 110 may include a first transistor positioned on the substrate 4100 and an organic light emitting element electrically connected to the first transistor.

The first transistor may include a first active layer 4121, a first gate electrode layer 4122, a first source electrode layer 4123, and a first drain electrode layer 4124.

The organic light emitting element includes an anode electrode 4310, a light emitting layer 4320, and a cathode electrode 4340.

Referring to FIG. 4, a light blocking layer 4127 may be disposed on the substrate 4100.

A first buffer layer 4110 may be disposed on the substrate 4100 and the light blocking layer 4127, and a second buffer layer 4111 may be disposed on the first buffer layer 4110.

The first active layer 4121 of the first transistor may be disposed on the second buffer layer 4111.

The first gate insulation layer 4112 may be disposed on the first active layer 4121, and the first gate electrode layer 4122 may be disposed on the first gate insulation layer 4112.

A first interlayer insulation layer 4113 may be disposed on the first gate electrode layer 4122, a third buffer layer 4114 may be disposed on the first interlayer insulation layer 4113, a second gate insulation layer 4115 may be disposed on the third buffer layer 4114, and a second interlayer insulation layer 4116 may be disposed on the second gate insulation layer 4115.

The light blocking electrode layer 4128, the first source electrode layer 4123, and the first drain electrode layer 4124 may be disposed on the second interlayer insulation layer 4116.

The first source electrode layer 4123 and the first drain electrode layer 4124 may be disposed to be spaced apart from each other on the second interlayer insulation layer 4116.

Each of the first source electrode layer 4123 and the first drain electrode layer 4124 may contact the first active layer 4121 through holes formed in the first gate insulation layer 4112, the first interlayer insulation layer 4113, the third buffer layer 4114, the second gate insulation layer 4115, and the second interlayer insulation layer 4116.

As described above, the first transistor may be disposed on the substrate 4100, but the structure of the first transistor according to embodiments of the disclosure is not limited thereto.

As another example, the first gate electrode layer 4122 may be disposed on the substrate 4100, the first active layer 4121 may be disposed on the first gate electrode layer 4122, the first source electrode layer 4123 may be disposed on the first active layer 4121 to overlap one end of the first active layer 4121, and the first drain electrode layer 4124 may be disposed to overlap the other end of the first active layer 4121.

An insulation layer 4210 may be disposed to cover the first transistor.

The insulation layer 4210 may be formed of an organic material, but embodiments of the disclosure are not limited thereto.

The insulation layer 4210 may include a first insulation layer 4211, a second insulation layer 4212, and a third insulation layer 4213.

Specifically, the first insulation layer 4211 covering the first transistor may be disposed, the second insulation layer 4212 may be disposed on the first insulation layer 4121, and the third insulation layer 4213 may be disposed on the second insulation layer 4212.

However, the disclosure is not necessarily limited thereto, and the insulation layer 4210 may be a single insulation layer, and is not limited to a multilayer film.

Meanwhile, the light emitting layer 4320 of the organic light emitting element may be disposed on the anode electrode 4310 that does not overlap the bank layer 4330.

The bank layer 4330 may cover at least a portion of the light emitting layer 4320.

The cathode electrode 4340 of an organic light emitting element may be disposed on the light emitting layer 4320.

Meanwhile, the light emitting layer 4320 of the organic light emitting element may be formed by a deposition or coating method having straightness.

For example, the light emitting layer 4320 may be formed by physical vapor deposition (PVD).

The light emitting layer 4320 formed in this way may have a thickness in an area having a predetermined angle with respect to the substrate 4100 that is thinner than a thickness in an area parallel to the substrate 4100.

The light emitting layer 4320 may include a red organic light emitting layer disposed in the red subpixel, a green organic light emitting layer disposed in the green subpixel, and a blue organic light emitting layer disposed in the blue subpixel.

FIG. 4 illustrates an example in which the light emitting layer 4320 is a green organic light emitting layer.

Meanwhile, the anode electrode 4310 may include a reflective metal.

FIG. 4 illustrates a configuration in which the anode electrode 4310 is a single layer, but embodiments of the disclosure are not limited thereto, and may be formed of multiple layers.

For example, when the anode electrode 4310 is formed of multiple layers, at least one layer may include a reflective metal.

For example, the anode electrode 4310 may include at least one of aluminum, neodymium, nickel, titanium, tantalum, copper (Cu), silver (Ag), and an aluminum alloy, but embodiments of the disclosure are not limited thereto.

The cathode electrode 4340 may contain a conductive material through which light is transmitted or semi-transmitted.

For example, it may include at least one type of transparent conductive oxide such as indium tin oxide (ITO), indium zinc oxide (IZO), indium tin zinc oxide (ITZO), zinc oxide, tin oxide, or the like, or a transflective metal such as magnesium, silver (Ag), or an alloy of magnesium and silver.

Here, when the cathode electrode 4340 includes a transflective metal, the thickness of the cathode electrode 4340 may be smaller than the thickness of the anode electrode 4310.

Meanwhile, a light blocking layer 4127, a light blocking electrode layer 4128 electrically connected to the light blocking layer 4127, and a second metal pattern layer 4129 positioned on the first insulation layer 4211 may be disposed on the substrate 4100.

The light blocking layer 4127 may perform a capacitor function or a function of blocking light entering from the rear surface.

The light blocking electrode layer 4128 may contact the light blocking layer 4127 through holes formed in the first buffer layer 4110, the second buffer layer 4111, the first gate insulation layer 4112, the first interlayer insulation layer 4113, the third buffer layer 4114, the second gate insulation layer 4115, and the second interlayer insulation layer 4116.

The second metal pattern layer 4129 may contact the first source electrode layer 4123 through a hole formed in the first insulation layer 4211, and may contact the anode electrode 4310 through holes formed in the second insulation layer 4212 and the third insulation layer 4213.

In other words, the second metal pattern layer 4219 may serve to electrically connect the first source electrode layer 4123 and the anode electrode 4310.

Further, as shown in FIG. 4, a storage capacitor may be disposed in the active area.

The storage capacitor may include a first storage capacitor electrode layer 4125, which is disposed on the same layer as the first gate electrode layer 4122, and a second storage capacitor electrode layer 4126, which is disposed on the first interlayer insulation layer 4113, but the structure of the storage capacitor according to embodiments of the disclosure is not limited thereto.

As illustrated in FIG. 4, the second storage capacitor electrode layer 4126 may form a capacitor with the first storage capacitor electrode layer 4125.

The second active layer 4131 of the second transistor may be disposed on the third buffer layer 4114.

The second gate insulation layer 4115 may be disposed on the second active layer 4131, and the second gate electrode layer 4131 may be disposed on the second gate insulation layer 4115.

A second interlayer insulation layer 4116 may be disposed on the second gate electrode layer 4131, and an insulation layer 4210 may be disposed on the second interlayer insulation layer 4116.

The second source electrode layer 4132 and the second drain electrode layer 4133 may be disposed on the second interlayer insulation layer 4116.

The second source electrode layer 4132 and the second drain electrode layer 4133 may be disposed to be spaced apart from each other on the second interlayer insulation layer 4116.

Each of the second source electrode layer 4132 and the second drain electrode layer 4133 may contact the second active layer 4130 through a hole formed in the second interlayer insulation layer 4116 and the second gate insulation layer 4115.

Meanwhile, at least one spacer 4331 may be disposed between the cathode electrode 4340 and the bank layer 4330.

The spacer 4331 may be formed of the same material as the bank layer 4330, but embodiments of the disclosure are not limited thereto.

The bank layer 4330 and the spacer 4331 may be formed of a transparent insulating material.

The transmittance of the bank layer 4330 may be higher than the transmittance of the third insulation layer 4213.

Meanwhile, at least one or more encapsulation layers 4350 may be disposed on the cathode electrode 4340 of the organic light emitting element.

The encapsulation layer 4350 may include a first encapsulation layer 4351 disposed on the cathode electrode 4340, a second encapsulation layer 4352 disposed on the first encapsulation layer 4351, and a third encapsulation layer 4353 disposed on the second encapsulation layer 4352.

As such, when the encapsulation layer 4350 is formed of multiple layers, at least one layer may include an inorganic insulating material, and at least one other layer may include an organic insulating material.

In an embodiment of the disclosure, the first encapsulation layer 4351 and the third encapsulation layer 4353 may include an inorganic insulating material, and the second encapsulation layer 4352 may include an organic insulating material, but embodiments of the disclosure are not limited thereto.

The encapsulation layer 4350 may be disposed on the organic light emitting element to prevent moisture, foreign substances, or the like from penetrating into the organic light emitting element.

A touch buffer layer 4360 may be disposed on the third encapsulation layer 4353, and a touch interlayer insulation layer 4370 may be disposed on the touch buffer layer 4360.

A plurality of touch sensors 4410 may be disposed on the touch interlayer insulation layer 4370.

The touch sensors 4410 may be transparent or opaque.

A passivation layer 4380 may be disposed on the plurality of touch sensors 4410.

A plurality of black matrices 4420 may be disposed on the passivation layer 4380.

The black matrix 4420 may be formed of a material having low reflectivity.

For example, the black matrix 4420 may include carbon black, a dye, or a resin.

It may include color filters CF1 and CF2 positioned on the passivation layer 4380 and positioned in an area corresponding to the opening area of the bank layer 4330.

In FIG. 4, a green color filter CF1 and a blue color filter CF2 are disposed between a plurality of black matrices 4420.

A display device having high luminance efficiency may be provided by including color filters CF1 and CF2.

The overcoat layer 4390 may be disposed on the passivation layer 4380 to cover the plurality of black matrices 4420 and the color filters CF1 and CF2.

The overcoat layer 4390 may prevent moisture, foreign substances, or the like from penetrating, thereby preventing a metal or the like from being corroded by reacting with moisture in the air.

A first connection pattern and a second connection pattern may be contacted by a hole formed in the touch interlayer insulation layer 4370.

The cross-sectional view of the display panel 110 has been described above with reference to FIG. 4.

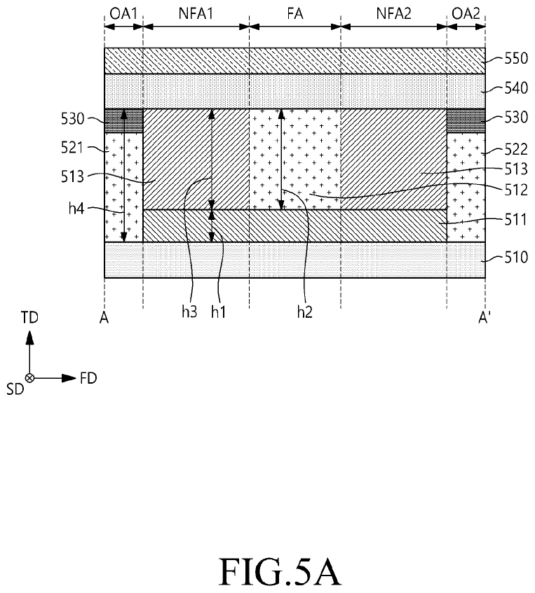

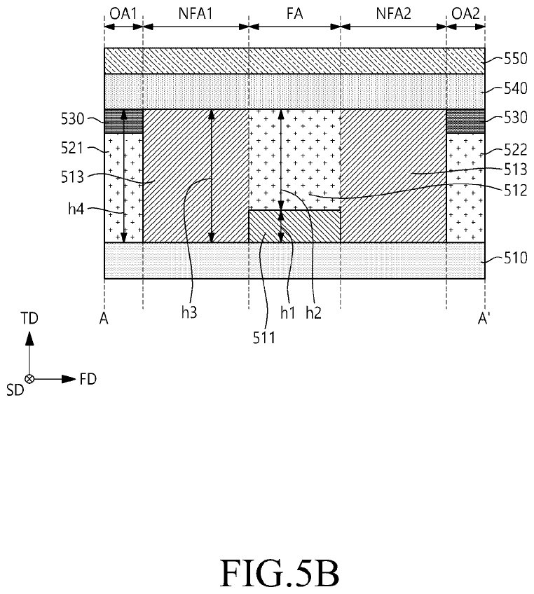

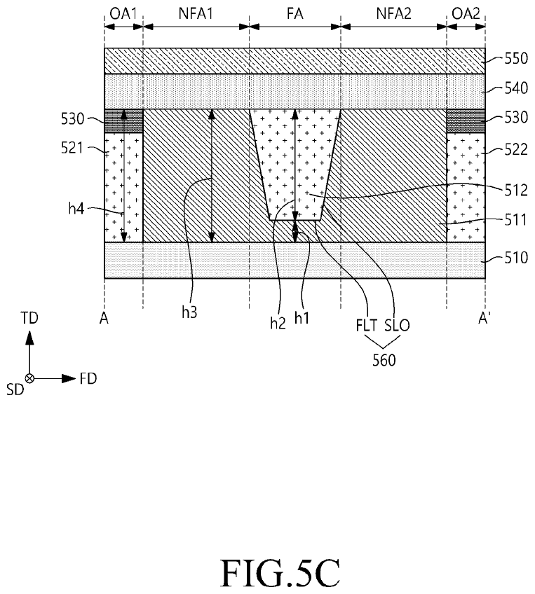

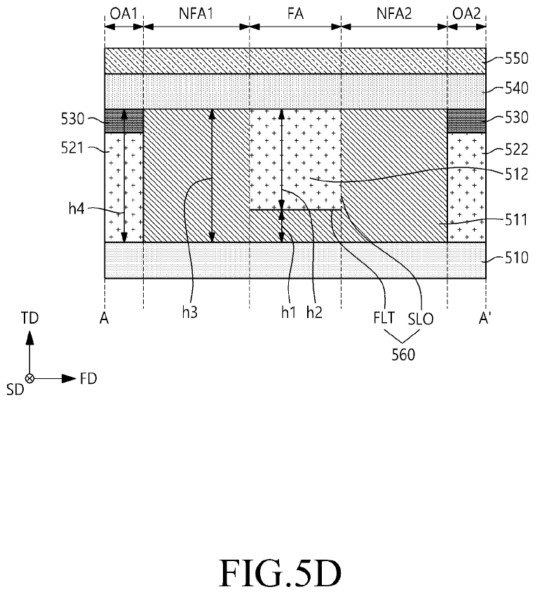

Hereinafter, cross-sectional structures positioned on the display panel 510 are described with reference to FIGS. 5A to 5D.

Here, the matters regarding the display panel 510 of FIGS. 5A to 5D may be substantially the same as those regarding the display panel 110 described with reference to FIG. 4.

In the disclosure, when A is substantially the same as B, it may mean that A and B are regarded as the same considering a tiny difference due to a processing error.

FIGS. 5A, 5B, 5C, and 5D are views illustrating an example of a cross-sectional structure taken along A-A′ of FIG. 1A.

Referring to FIGS. 5A to 5D, a display device may include a first non-folding area NFA1, a second non-folding area NFA2 spaced apart from the first non-folding area NFA1, and a folding area FA positioned between the first non-folding area NFA1 and the second non-folding area NFA2 with respect to the first direction FD.

The first non-folding area NFA1 may be positioned between a first outer area OA1 and the folding area FA, and the second non-folding area NFA2 may be positioned between a second outer area OA2 and the folding area FA.

In the disclosure, the first outer area OA1 is not limited to an area other than the first non-folding area NFA1. For example, the first outer area OA1 may be a partial area of the first non-folding area NFA1.

Likewise, in the disclosure, the second outer area OA2 is not limited to an area other than the second non-folding area NFA2. For example, the second outer area OA2 may be a partial area of the second non-folding area NFA2.

However, in the disclosure, for convenience of description, the first outer area OA1 and the second outer area OA2, and the first non-folding area NFA1 and the second non-folding area NFA2 are separately described.

Referring to FIGS. 5A to 5D, a first adhesive member 511 may be positioned on the display panel 510, may be disposed in the folding area FA, and may include an ultraviolet absorbing material.

Further, a second adhesive member 512 may be positioned on the first adhesive member 511 in the folding area FA.

The second adhesive member 512 may include, but is not limited to, an ultraviolet absorbing material.

For example, when the second adhesive member 512 includes an ultraviolet absorbing material, the mole percent of the ultraviolet absorbing material included in the second adhesive member 512 may be smaller than the mole percent of the ultraviolet absorbing material included in the first adhesive member 511.

As another example, the second adhesive member 512 may not include an ultraviolet absorbing material.

When the second adhesive member 512 does not include an ultraviolet absorbing material or includes less than the first adhesive member 511, the second adhesive member 512 positioned in the folding area FA is more exposed by ultraviolet rays UV incident from the cover glass 540 to the first adhesive member 511 than the first adhesive member 511 positioned in the first non-folding area NFA1 and the second non-folding area NFA2, so that the adhesive force of the folding area FA is higher than the adhesive force of the first non-folding area NFA1 and the second non-folding area NFA2.

Accordingly, since the adhesive force of the folding area FA is higher than the adhesive force of the first non-folding area NFA1 and the second non-folding area NFA2, delamination of the folding area FA may be prevented.

Further, the adhesive members 511 and 512 adjacent to the display panel 510 in the folding area FA may be divided into two portions, e.g., a portion (i.e., 511) having a high UV absorption rate and a portion (i.e., 512) having a low UV absorption rate positioned on the portion having the high UV absorption rate, thereby increasing the reliability of the flexible display to which the color filter layer is applied.

The ultraviolet absorbing material may be at least one of benzotriazole, triazin, and benzophenone, but is not limited thereto.

Benzotriazole-based ultraviolet absorbing materials may include, e.g., 2-(2′-hydroxy-5′-methylphenyl)benzotriazole, 2-(2′-hydroxy-3′-tert-butyl-5′-methylphenyl)-5-chlorobenzotriazole, 2-(2′-hydroxy-3′,5′-di-tert-butylphenyl)-5-chlorobenzotriazole, 2-(2′-hydroxy-3′,5′-di-tert-amylphenyl)benzotriazole, 2-(2H-benzotriazole-2-yl)-4-(1,1,3,3-tetramethylbutyl)phenol.

The triazine-based ultraviolet absorbing materials may include, e.g., 2-(4,6-diphenyl-1,3,5-triazin-2-yl)-5-hexyloxyphenol, 2-[4,6-bis(2,4-dimethylphenyl)-1,3,5-triazin-2-yl]-5-(octyloxy)phenol.

The benzophenone-based ultraviolet absorbing material may include, e.g., 2-hydroxy-4-n-octoxybenzophenone.

Meanwhile, the display device may include a first barrier layer 521 overlapping the first outer area OA1 and a second barrier layer 522 overlapping the second outer area OA2.

By disposing the first barrier layer 521 and the second barrier layer 522 in the first outer area OA1 and the second outer area OA2, respectively, it is possible to prevent moisture from penetrating and prevent whitening of adhesive members.

Further, since the first barrier layer 521 and the second barrier layer 522 have a higher modulus than the adhesive member, evaporation of adhesives of the first outer area OA1 and the second outer area OA2 may be prevented.

The first barrier layer 521 and the second barrier layer 522 may include rubber or acrylic resin, but are not limited thereto.

The first barrier layer 521 and the second barrier layer 522 may have a water vapor transmission rate (WVTR) of 4.5 to 60 g/m³/day, but are not limited thereto.

In the disclosure, the water vapor transmission rate (WVTR) is a measure of the degree of water vapor passing through the barrier layers 521 and 522.

The water vapor transmission rate decreases as the thickness of the barrier layers 521 and 522 increases, and increases as the temperature increases.

When the first barrier layer 521 and the second barrier layer 522 include rubber or acrylic resins, the water vapor transmission rate (WVTR) may be lowered to delay water penetration.

The storage modulus of the first barrier layer 521 and the second barrier layer 522 may be 8.43×10⁴ to 2.05×10⁶ Pa at −20° C., 3.93×10⁴ to 2.21×10⁵ Pa at 25° C., and 3.03×10⁴ to 1.73×10⁵ Pa at 60° C., but is not limited thereto.

In the disclosure, the storage modulus is a parameter indicating how elastically a material reacts to external stress.

The higher the storage modulus, the stronger resistance to external stress the material has.

In the first outer area OA1 and the second outer area OA2, the black matrix 530 may be disposed on the first barrier layer 521 and the second barrier layer 522, respectively.

When the black matrix 530 is disposed on the first barrier layer 521 and the second barrier layer 522, ultraviolet rays UV incident from the cover glass 540 toward the display panel 510 may not pass through the black matrix 530.

Meanwhile, the cover glass 540 may be positioned over the entire area on the black matrix 530 and the second adhesive member 512.

A protective layer 550 may be disposed on the cover glass 540.

The configuration commonly applied to FIGS. 5A to 5D has been described above.

Hereinafter, each drawing is described in detail.

Referring to FIG. 5A, in the first non-folding area NFA1, the folding area FA and the second non-folding area NFA2, the first adhesive member 511 may be disposed on the display panel 510, and a third adhesive member 513 including an ultraviolet absorbing material may be included on the first adhesive member 511 in the first non-folding area NFA1 and the second non-folding area NFA2.

In this case, the thickness h2 of the second adhesive member 512 and the thickness h3 of the third adhesive member 513 are not particularly limited, but it is preferable that the thickness h2 of the second adhesive member 512 and the thickness h3 of the third adhesive member 513 are the same.

Further, the sum h1+h3 of the thickness of the first adhesive member 511 and the thickness of the third adhesive member 513 may be larger than the thickness hl of the first adhesive member 511.

Further, the amounts of ultraviolet absorbing materials of the first adhesive member 511, the second adhesive member 512, and the third adhesive member 513 may be different.

Preferably, the mole percents of the ultraviolet absorbing materials of the first adhesive member 511 and the third adhesive member 513 may be larger than the mole percent of the ultraviolet absorbing material of the second adhesive member 512. The mole percents of the ultraviolet absorbing materials of the first adhesive member 511 and the third adhesive member 513 may be the same.

More preferably, only the first adhesive member 511 and the third adhesive member 513 may include an ultraviolet absorbing material, and the second adhesive member 512 may not include an ultraviolet absorbing material.

In other words, the mole percent of the ultraviolet absorbing material of the second adhesive member 512 may be 0 mol %.

Meanwhile, referring to FIG. 5A, the sum h4 of the thicknesses of at least one of the first barrier layer 521 and the second barrier layer 522 and the black matrix 530 may be equal to or larger than the sum h1+h2 of the thicknesses of the first adhesive member 511 and the second adhesive member 512, or be preferably the same.

When the sum h4 of the thicknesses of at least one of the first barrier layer 521 and the second barrier layer 522 and the black matrix 530 is equal to or larger than the sum h1+h2 of the thicknesses of the first adhesive member 511 and the second adhesive member 512, moisture penetration from the outside may be effectively blocked and evaporation of adhesives may be prevented.

FIG. 5A has been described above in detail, and FIG. 5B is described in detail below.

Referring to FIG. 5B, a third adhesive member 513 may be included that is disposed on the display panel 510 in the first non-folding area NFA1 and the second non-folding area NFA2 and includes an ultraviolet absorbing material.

In this case, the thickness h3 of the third adhesive member 513 is not particularly limited, but is preferably larger than the thickness hl of the first adhesive member 511.

More preferably, the thickness h3 of the third adhesive member 513 may be equal to the sum h1+h2 of the thickness of the first adhesive member 511 and the thickness of the second adhesive member 512.

Matters regarding the first barrier layer 521 and the second barrier layer 522 of FIG. 5B may be substantially the same as those regarding the first barrier layer 521 and the second barrier layer 522 described with reference to FIG. 5A.

Further, the amounts of ultraviolet absorbing materials of the first adhesive member 511, the second adhesive member 512, and the third adhesive member 513 may be different.

Preferably, the mole percents of the ultraviolet absorbing materials of the first adhesive member 511 and the third adhesive member 513 may be larger than the mole percent of the ultraviolet absorbing material of the second adhesive member 512. The mole percents of the ultraviolet absorbing materials of the first adhesive member 511 and the third adhesive member 513 may be the same.

More preferably, only the first adhesive member 511 and the third adhesive member 513 may include an ultraviolet absorbing material, and the second adhesive member 512 may not include an ultraviolet absorbing material.

In other words, the mole percent of the ultraviolet absorbing material of the second adhesive member 512 may be 0 mol %.

FIG. 5B has been described above in detail, and FIGS. 5C and 5D are described below in detail.

Referring to FIGS. 5C and 5D, a first adhesive member 511 including a concave portion 560 overlapping the folding area FA and including an ultraviolet absorbing material may be positioned on the display panel 510.

The concave portion 560 may include a flat portion FLT and an inclined portion SLO surrounding the flat portion FLT.

A second adhesive member 512 may be disposed in the concave portion 560 of the first adhesive member 511.

Matters regarding the first barrier layer 521 and the second barrier layer 522 of FIGS. 5C and 5D may be substantially the same as those regarding the first barrier layer 521 and the second barrier layer 522 described with reference to FIG. 5A.

The amounts of ultraviolet absorbing materials of the first adhesive member 511 and the second adhesive member 512 may be different.

Preferably, the mole percent of the ultraviolet absorbing material of the first adhesive member 511 may be larger than the mole percent of the ultraviolet absorbing material of the second adhesive member 512.

More preferably, only the first adhesive member 511 may include an ultraviolet absorbing material, and the second adhesive member 512 may not include an ultraviolet absorbing material.

In other words, the mole percent of the ultraviolet absorbing material of the second adhesive member 512 may be 0 mol %.

The thickness h2 of the second adhesive member 512 may be equal to a value obtained by subtracting the thickness h1 of the first adhesive member 511 of the folding area FA from the thickness h3 of the first adhesive member 511 of the area other than the folding area FA.

In other words, the depth of the concave portion 560 may be substantially the same as the thickness h2 of the second adhesive member 512.

The angle formed by the flat portion FLT and the inclined portion SLO is not particularly limited, but it is preferable that the angle formed by the flat portion FLT and the inclined portion SLO is a right angle as shown in FIG. 5D.

Meanwhile, referring to FIGS. 5C and 5D, the sum h4 of the thicknesses of at least one of the first barrier layer 521 and the second barrier layer 522 and the black matrix 530 may be equal to or larger than the sum h1+h2 of the thicknesses of the first adhesive member 511 and the second adhesive member 512, and be preferably the same. That is, the sum h4 of thicknesses of at least one of the first barrier layer 521 and the second barrier layer 522 and the black matrix 530 may be equal to a thickness h3 of the first adhesive member 511 in an area other than the folding area FA.

When the sum h4 of the thicknesses of at least one of the first barrier layer 521 and the second barrier layer 522 and the black matrix 530 is equal to or larger than the sum h1+h2 of the thicknesses of the first adhesive member 511 and the second adhesive member 512, moisture penetration from the outside may be effectively blocked and evaporation of adhesives may be prevented.

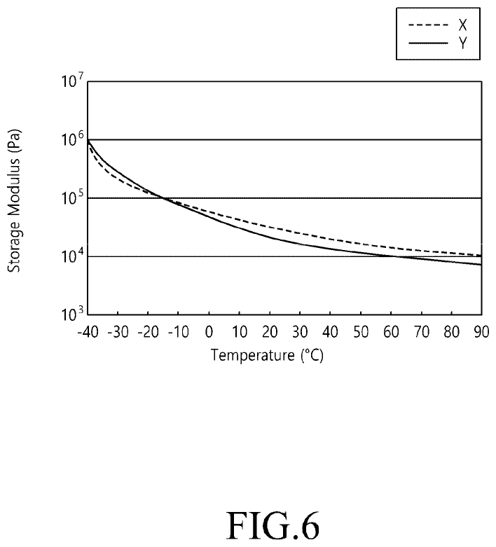

FIG. 6 is a graph illustrating changes in value depending on the presence or absence of a UV absorbing material of an adhesive member in a display device according to embodiments of the disclosure.

Referring to FIG. 6, the graph differs between when the adhesive member does not include an ultraviolet absorbing material (X) and when the adhesive member includes an ultraviolet absorbing material (Y).

Specifically, at less than −20° C., it is shown that the storage modulus is higher when the ultraviolet absorbing material is included (Y) than when the ultraviolet absorbing material is not included (X).

On the other hand, at −20° C. or higher, the storage modulus is higher when the ultraviolet absorbing material is not included (X) than when the ultraviolet absorbing material is included (Y).

Therefore, when the ultraviolet absorbing material is included (Y), folding is not easy because the storage modulus is high at −20° C. or lower, whereas folding is easy because the storage modulus is low at −20° C. or higher.

From FIG. 6, it is possible to increase the reliability of the folding area in low-temperature and high-temperature environments by adjusting the thickness or content of the adhesive member including the ultraviolet absorbing material and the adhesive member not including the ultraviolet absorbing material.

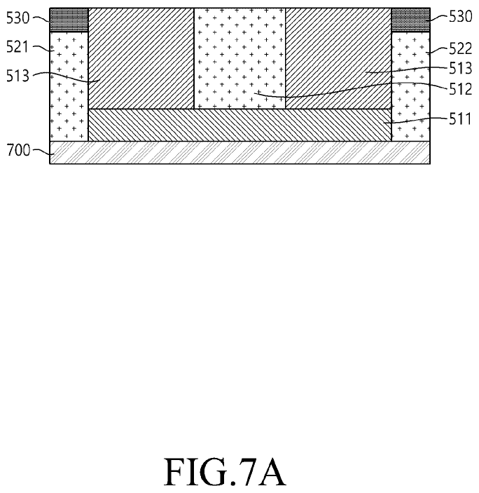

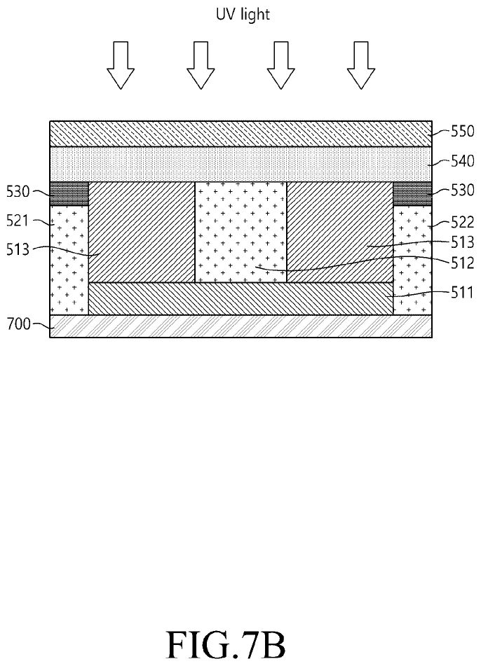

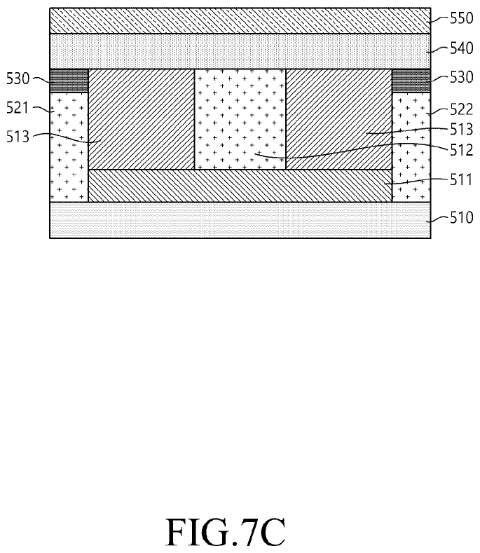

FIGS. 7A, 7B, and 7C are views schematically illustrating a process of forming a structure of a display device according to embodiments of the disclosure.

The display panel 510, the first adhesive member 511, the second adhesive member 512, the third adhesive member 513, the cover glass 540, the first barrier layer 521, the second barrier layer 522, the black matrix 530, and the protective layer 550 of FIGS. 7A to 7C may be substantially the same as the display panel 510, the first adhesive member 511, the second adhesive member 512, the third adhesive member 513, the cover glass 540, the first barrier layer 521, the second barrier layer 522, the black matrix 530, and the protective layer 550 described with reference to FIGS. 5A to 5D.

Referring to FIG. 7A, the first adhesive member 511, the second adhesive member 512, the third adhesive member 513, the first barrier layer 521, the second barrier layer 522, and the black matrix 530 may be positioned on the protective film 700.

Then, referring to FIG. 7B, the cover glass 540 may be disposed on the black matrix 530, the second adhesive member 512, and the third adhesive member 513, and the protective layer 550 may be disposed on the cover glass 540.

The adhesive force between the second adhesive member 512 and the third adhesive member 513 and the cover glass 540 may be increased by exposure ultraviolet rays UV incident from the cover glass 540 to the first adhesive member 511.

In this case, the second adhesive member 512 has a lower mole percent of the ultraviolet absorbing material than the third adhesive member 513, and thus the adhesive force between the second adhesive member 512 and the cover glass 540 may be higher than the adhesive force between the third adhesive member 513 and the cover glass 540 due to UV exposure.

Then, referring to FIG. 7C, after removing the protective film 700 of FIG. 7B, the display panel 510 may be disposed at the place where the protective film 700 was positioned.

Embodiments of the disclosure described above are briefly described below.

A display device according to embodiments of the disclosure may comprise a substrate including a first non-folding area, a second non-folding area, and a folding area positioned between the first non-folding area and the second non-folding area, a plurality of light emitting elements disposed on the substrate, an encapsulation layer disposed on the plurality of light emitting elements, a color filter layer disposed on the encapsulation layer, a first adhesive member positioned on the color filter layer, disposed in the folding area, and including an ultraviolet absorbing material of a first mole percent, and a second adhesive member disposed on the first adhesive member in the folding area and including the ultraviolet absorbing material of a second mole percent smaller than the first mole percent.

In the display device according to embodiments of the disclosure, the second mol percent may be 0 mol %.

In the display device according to embodiments of the disclosure, the first adhesive member may be further disposed on the color filter layer in the first non-folding area and the second non-folding area. A third adhesive member including an ultraviolet absorbing material of a third mole percent may be further included on the first adhesive member in the first non-folding area and the second non-folding area.

In the display device according to embodiments of the disclosure, a thickness of the second adhesive member may be identical to a thickness of the third adhesive member.

The display device according to embodiments of the disclosure may further comprise a third adhesive member positioned on the color filter layer, disposed in the first non-folding area and the second non-folding area, and including an ultraviolet absorbing material of a third mole percent.

In the display device according to embodiments of the disclosure, a thickness of the third adhesive member may be larger than a thickness of the first adhesive member.

In the display device according to embodiments of the disclosure, the thickness of the third adhesive member may be equal to a sum of the thickness of the first adhesive member and the thickness of the second adhesive member.

In the display device according to embodiments of the disclosure, the third mole percent may be larger than the second mole percent.

In the display device according to embodiments of the disclosure, the first mole percent and the third mole percent may be the same.

In the display device according to embodiments of the disclosure, the ultraviolet absorbing material may include at least one of benzotriazole, triazin, and benzophenone.

In the display device according to embodiments of the disclosure, the substrate may further include a first outer area adjacent to the first non-folding area and a second outer area adjacent to the second non-folding area. The display device may further comprise a first barrier layer overlapping the first outer area and a second barrier layer overlapping the second outer area.

In the display device according to embodiments of the disclosure, a black matrix may be positioned on the first barrier layer and the second barrier layer. A sum of thicknesses of at least one of the first barrier layer and the second barrier layer and the black matrix may be equal to a sum of thicknesses of the first adhesive member and the second adhesive member.

A display device according to embodiments of the disclosure may comprise a substrate including a first non-folding area, a second non-folding area, and a folding area positioned between the first non-folding area and the second non-folding area, a plurality of light emitting elements disposed on the substrate, an encapsulation layer disposed on the plurality of light emitting elements, a color filter layer disposed on the encapsulation layer, a first adhesive member positioned on the color filter layer, including a concave portion including a flat portion and an inclined portion surrounding the flat portion and overlapping the folding area, and including an ultraviolet absorbing material of a first mole percent, and a second adhesive member positioned in the concave portion of the first adhesive member, and including the ultraviolet absorbing material of a second mole percent smaller than the first mole percent.

In the display device according to embodiments of the disclosure, the second mol percent may be 0 mol %.

In the display device according to embodiments of the disclosure, a depth of the concave portion may be equal to a thickness of the second adhesive member.

In the display device according to embodiments of the disclosure, the ultraviolet absorbing material may include at least one of benzotriazole, triazin, and benzophenone.

In the display device according to embodiments of the disclosure, a thickness of the second adhesive member may be equal to a value obtained by subtracting a thickness of the first adhesive member of the folding area from a thickness of the first adhesive member of an area other than the folding area.

In the display device according to embodiments of the disclosure, a right angle may be formed by the inclined portion and the flat portion.

In the display device according to embodiments of the disclosure, the substrate may further include a first outer area adjacent to the first non-folding area and a second outer area adjacent to the second non-folding area. The display device may further comprise a first barrier layer overlapping the first outer area and a second barrier layer overlapping the second outer area.

In the display device according to embodiments of the disclosure, a black matrix may be positioned on the first barrier layer and the second barrier layer. A sum of thicknesses of at least one of the first barrier layer and the second barrier layer and the black matrix may be equal to a thickness of the first adhesive member in an area other than the folding area.

A display device according to embodiments of the disclosure may comprise a substrate including a first non-folding area, a second non-folding area, and a folding area positioned between the first non-folding area and the second non-folding area, a plurality of light emitting elements disposed on the substrate, an encapsulation layer disposed on the plurality of light emitting elements, a color filter layer disposed on the encapsulation layer, and an adhesive member disposed on the color filter layer, disposed in the folding area, and including a first portion adjacent to the color filter layer and a second portion on the first portion, wherein an ultraviolet absorption rate of the first portion is larger than an ultraviolet absorption rate of the second portion.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a first non-folding area, a second non-folding area, and a folding area between the first non-folding area and the second non-folding area;
a plurality of light emitting elements disposed on the substrate;
an encapsulation layer disposed on the plurality of light emitting elements;
a color filter layer disposed on the encapsulation layer;
a first adhesive member positioned on the color filter layer, the first adhesive member disposed in the folding area and including a first ultraviolet absorbing material of a first mole percent; and
a second adhesive member disposed on the first adhesive member, the second adhesive member disposed in the folding area and including a second ultraviolet absorbing material of a second mole percent less than the first mole percent.

2. The display device of claim 1, wherein the second mole percent is 0 mol %.

3. The display device of claim 1, wherein the first adhesive member is further disposed on the color filter layer in the first non-folding area and the second non-folding area, the display device further comprising:
a third adhesive member including a third ultraviolet absorbing material of a third mole percent, the third adhesive member disposed on the first adhesive member in the first non-folding area and the second non-folding area.

4. The display device of claim 3, wherein a thickness of the second adhesive member is equal to a thickness of the third adhesive member.

5. The display device of claim 1, further comprising:
a third adhesive member positioned on the color filter layer, the third adhesive member disposed in the first non-folding area and the second non-folding area, and the third adhesive member including a third ultraviolet absorbing material of a third mole percent.

6. The display device of claim 5, wherein a thickness of the third adhesive member is greater than a thickness of the first adhesive member.

7. The display device of claim 6, wherein the thickness of the third adhesive member is equal to a sum of the thickness of the first adhesive member and a thickness of the second adhesive member.

8. The display device of claim 3, wherein the third mole percent is larger than the second mole percent.

9. The display device of claim 8, wherein the first mole percent and the third mole percent are equal.

10. The display device of claim 1, wherein at least one of the first ultraviolet absorbing material and the second ultraviolet absorbing material includes one or more of benzotriazole, triazin, and benzophenone.

11. The display device of claim 1, wherein the substrate further includes a first outer area adjacent to the first non-folding area and a second outer area adjacent to the second non-folding area, the display device further comprising:
a first barrier layer overlapping the first outer area; and
a second barrier layer overlapping the second outer area.

12. The display device of claim 11, further comprising:
a black matrix positioned on the first barrier layer and the second barrier layer,
wherein a sum of a thickness of at least one of the first barrier layer and the second barrier layer and a thickness of the black matrix is equal to a sum of a thickness of the first adhesive member and a thickness of the second adhesive member.

13. A display device, comprising:
a substrate including a first non-folding area, a second non-folding area, and a folding area positioned between the first non-folding area and the second non-folding area;
a plurality of light emitting elements disposed on the substrate;
an encapsulation layer disposed on the plurality of light emitting elements;
a color filter layer disposed on the encapsulation layer;
a first adhesive member positioned on the color filter layer, the first adhesive member including a concave portion overlapping the folding area and a first ultraviolet absorbing material of a first mole percent, wherein the concave portion includes a flat portion and an inclined portion surrounding the flat portion; and
a second adhesive member positioned in the concave portion of the first adhesive member, the second adhesive member including a second ultraviolet absorbing material of a second mole percent less than the first mole percent.

14. The display device of claim 13, wherein the second mole percent is 0 mol %.

15. The display device of claim 13, wherein a depth of the concave portion is equal to a thickness of the second adhesive member.

16. The display device of claim 13, wherein the first ultraviolet absorbing material or the second ultraviolet absorbing material includes at least one of benzotriazole, triazin, and benzophenone.

17. The display device of claim 13, wherein a thickness of the second adhesive member is equal to a value obtained by subtracting a thickness of the first adhesive member in the folding area from a thickness of the first adhesive member of an area excluding the folding area.

18. The display device of claim 13, wherein the inclined portion is perpendicular to the flat portion.

19. The display device of claim 13, wherein the substrate further includes a first outer area adjacent to the first non-folding area and a second outer area adjacent to the second non-folding area, the display device further comprising:
a first barrier layer overlapping the first outer area; and
a second barrier layer overlapping the second outer area.

20. The display device of claim 19, further comprising:
a black matrix positioned on the first barrier layer and the second barrier layer,
wherein a sum of thicknesses of at least one of the first barrier layer and the second barrier layer and the black matrix is equal to a thickness of the first adhesive member in an area other than the folding area.

21. A display device, comprising:
a substrate including a first non-folding area, a second non-folding area, and a folding area positioned between the first non-folding area and the second non-folding area;
a plurality of light emitting elements disposed on the substrate;
an encapsulation layer disposed on the plurality of light emitting elements;
a color filter layer disposed on the encapsulation layer; and
an adhesive member disposed on the color filter layer in the folding area, the adhesive member including a first portion adjacent to the color filter layer and a second portion on the first portion,
wherein an ultraviolet absorption rate of the first portion is greater than an ultraviolet absorption rate of the second portion.
